(19) United States
(12) Patent Application Publication
(10) Pub. No.: US 2025/0012836 A1
(43) Pub. Date: Jan. 9, 2025

(54) APPARATUSES, SYSTEMS, AND METHODS FOR INDIRECT ANTENNA TESTING

(71) Applicant: PLUME DESIGN, INC., Palo Alto, CA (US)

(72) Inventors: Miroslav SAMARDZIJA, Mountain View, CA (US); Arthur TUNG, San Jose, CA (US); Liem Hieu Dinh VO, San Jose, CA (US)

(21) Appl. No.: 18/347,747

(22) Filed: Jul. 6, 2023

(51) Int. Cl. G01R 29/08

(52) U.S. Cl. CPC G01R 29/0871; G01R 29/0807

(57) ABSTRACT

A disclosed indirect antenna testing apparatus may include (1) a Near Field Communication (NFC) interface that includes an NFC coil, the NFC interface dimensioned to receive a test NFC device while positioning the test NFC device within an effective range of the NFC coil, and (2) a Vector Network Analyzer (VNA) electrically coupled to the NFC coil and configured to (A) emit a signal via the NFC coil, and (B) monitor for a resonance from the test NFC device within at least one predetermined electromagnetic band. Various additional control devices, apparatuses, systems, and methods are also disclosed.

### BRIEF DESCRIPTION OF THE DRAWINGS

The accompanying drawings illustrate a number of example embodiments and are a part of the specification. Together with the following description, these drawings demonstrate and explain various principles of the instant disclosure.

FIG. 1 shows a perspective view of an example Near Field Communication (NFC) device (e.g., a smart ring device) that may be used in connection with some of the apparatuses, systems, and methods disclosed herein.

FIG. 2 shows a cross-section view of an example NFC device like the test NFC device shown in FIG. 1.

FIG. 3A shows a detailed view of an interior surface of an example NFC device.

FIG. 3B shows a detailed view of an interior surface of the example NFC device of FIG. 3A following an attempt to repair a connection defect.

FIG. 4 shows a block diagram of an example indirect antenna testing apparatus.

FIG. 5 includes a plot of resonances that a Vector Network Analyzer (VNA) may monitor for when testing a smart ring as an NFC device in accordance with some examples disclosed herein.

FIG. 6 is a block diagram of an example indirect antenna testing apparatus.

FIG. 7 includes a perspective view of an example NFC coil that may be included in and/or integrated into a test charger.

FIG. 8, FIG. 9, and FIG. 10 show perspective views of test chargers in accordance with some examples disclosed herein.

FIG. 11 includes a block diagram 1100 that illustrates using a smart ring device as an NFC interface in accordance with some examples disclosed herein.

FIG. 12 shows a perspective view of a test ring that may function as an NFC interface in accordance with some examples disclosed herein.

FIG. 13 includes a plot of resonances that a VNA may monitor for when testing a charger as an NFC device in accordance with some examples disclosed herein.

FIG. 14 is a block diagram of an example control device 1400 for indirect antenna testing.

FIG. 15 is a flow diagram of an example method 1500 for indirect antenna testing.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the instant disclosure covers all modifications, equivalents, and alternatives falling within the scope of the appended claims.

### DETAILED DESCRIPTION OF EXAMPLE EMBODIMENTS

Smart wearable devices, such as smart rings, smart watches, smart glasses, wristbands, key fobs, and trackers, typically have integrated wireless functionalities. These features are usually tested for performance and quality at the manufacturing or assembly factory before the products are dispatched to customers. This testing is generally done at the end of the production line using an Over-The-Air (OTA) test station, which measures the strength and quality of the communication link between the device and a Base Station (BS).

The OTA test station is an expensive and time-consuming tool, with factories typically charging for the testing time. As such, these stations are used at the end of the assembly line to test the fully assembled product, ensuring the quality and performance promised to customers.

However, certain design and manufacturing constraints pose challenges to this conventional testing process. Most smart wearables are both (1) physically small, and (2) must meet specific aesthetic standards. As a result, the internal components of these devices are usually sealed using a molding process. This molding process can make disassembly difficult, particularly in the case of molded smart rings. If a device fails at the end of the line, it's sent for failure analysis (FA) or repair, which often involves removing the molding to access internal parts. This can damage the molded parts beyond repair, making the product unfit for delivery or sale. Moreover, since most of the parts of modern wearable devices are heavily integrated and cannot be easily replaced once damaged, each failure adds to a scrap rate, reducing production yield and increasing manufacturing costs. Even a small scrap rate can lead to substantial financial losses. As a simplified example, a 0.1% scrap rate in a production run of 1 million smart rings, each costing $100 to manufacture, could lead to a $100,000 loss.

The present disclosure is generally directed to apparatuses, systems, and methods for indirect antenna testing. Embodiments of this disclosure may identify defects in smart wearable devices before they reach the final stage of assembly and molding. Embodiments may reduce costs and time associated with the traditional testing at OTA test stations. Indirect antenna testing as described herein may be significantly quicker than conventional antenna testing, taking only a few seconds compared to the several minutes required for conventional OTA testing, which may be crucial given that factories charge by the second for testing.

Moreover, some embodiments of the apparatuses, systems, and methods described herein can simultaneously test two wireless technologies present in a device, such as NFC and Bluetooth. Defective units may be removed from the assembly line and sent for repairs before the molding process, preventing further damage.

An example embodiment may include an indirect antenna testing apparatus that includes an NFC interface. The NFC interface may include an NFC coil and may be dimensioned to receive a test NFC device while positioning the test NFC device within an effective range of the NFC coil. The indirect antenna testing apparatus may also include a VNA. The VNA may be electrically coupled to the NFC coil (e.g., via a coaxial cable) and configured to (1) emit a signal via the NFC coil, and (2) monitor for a resonance from the test NFC device within a predetermined electromagnetic band. The electromagnetic band may represent an electromagnetic band used by a particular wireless technology. For example, the electromagnetic band may include 13.56 megahertz, which may correspond to a Bluetooth signal, and/or 2,400 megahertz, which may correspond to an NFC signal. If the VNA fails to detect a resonance from the test NFC device within the predetermined electromagnetic band, this may indicate a defect in the test NFC device.

In some embodiments, an indirect antenna testing apparatus may further include, and/or be included in a system that includes, a control device that performs various tasks for indirect antenna testing. For example, the control device may direct the VNA to emit the signal via the NFC coil and may direct the VNA to monitor for the resonance from the test NFC device. Additionally, the control device may further determine whether the VNA detects the resonance. Upon determining that the VNA detects the resonance, designates the test NFC device with a status of functional. Conversely, upon determining that the VNA does not detect the resonance, designates the test NFC device with a status of faulty. The control device may then record the determined status and/or report the determined status to a user.

Embodiments of the apparatuses, systems, and methods disclosed herein may present a number of advantages over conventional options for antenna testing, particularly in wearable devices. For example by sending a signal from the NFC coil and monitoring for a resonance from the test device, this indirect testing technique may reduce time and/or labor required for testing. Additionally, embodiments may be employed for effective early defect detection. By testing devices during the production phase, including those that are only partially assembled, defects can be identified early on. This can result in significant cost savings as faulty units may be detected before the completion of assembly or shipping. Additional or alternative benefits will be described and/or made apparent throughout the instant disclosure.

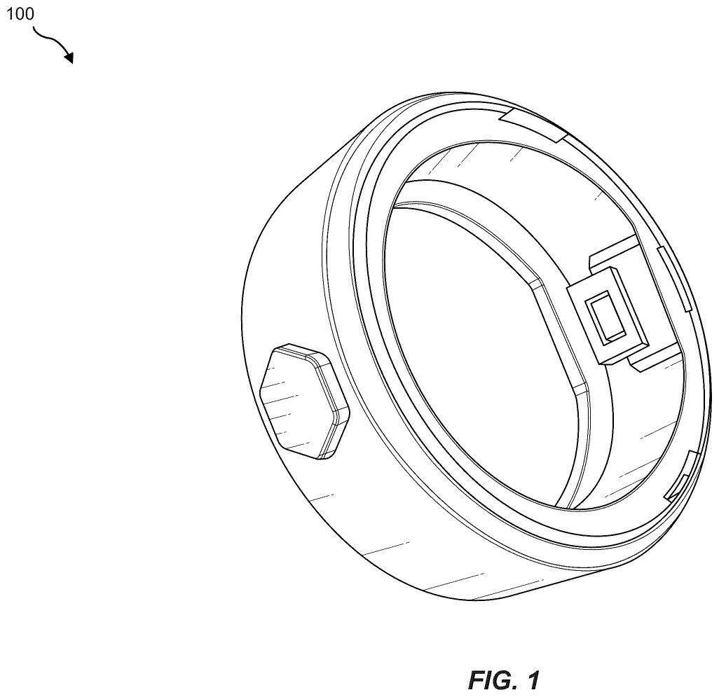

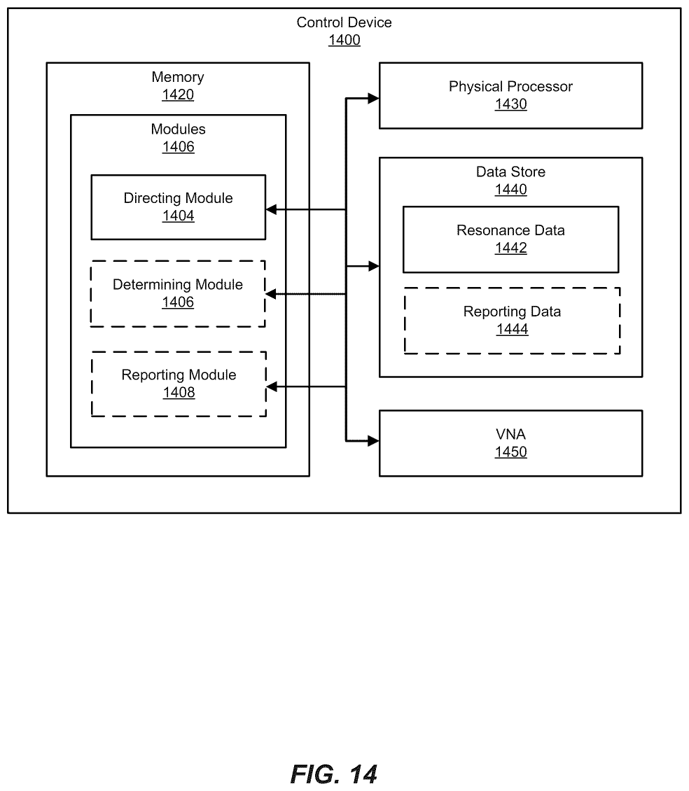

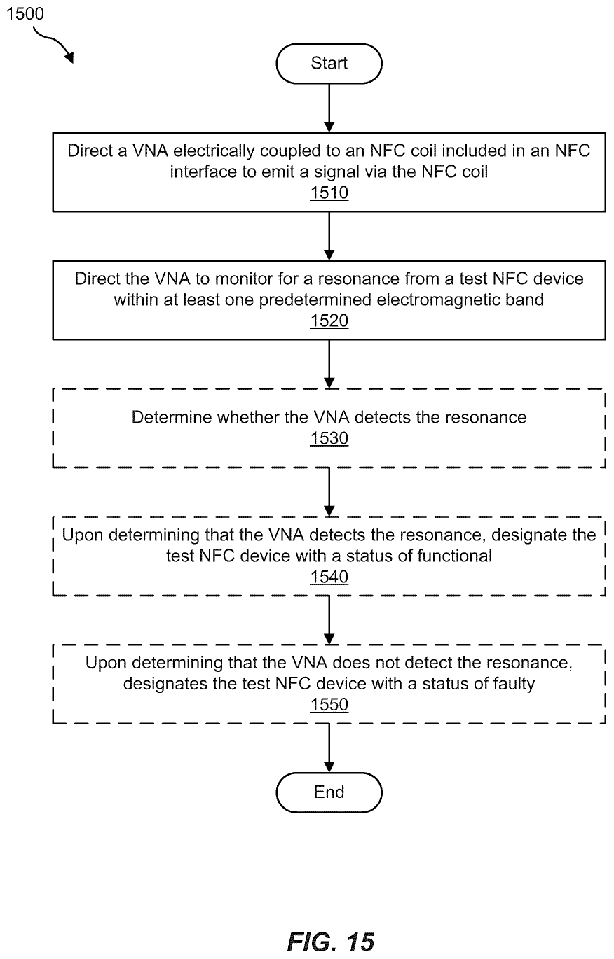

The following will provide, in reference to FIGS. 1-13, detailed descriptions of various apparatuses for indirect antenna testing. Detailed descriptions of various control devices or systems for indirect antenna testing will also be described in relation to FIG. 14. Moreover, detailed descriptions of corresponding methods of operation will also be provided in connection with FIG. 15.

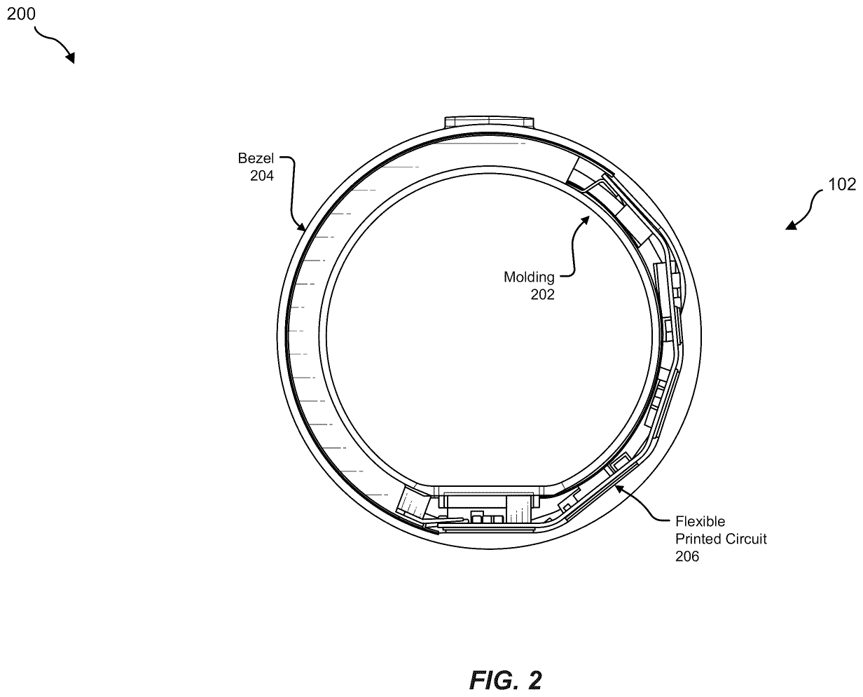

FIG. 1 shows a perspective view 100 of a possible test NFC device 102 that may be used in connection with the apparatuses, systems, and methods described herein. As shown, test NFC device 102 is a smart ring device. FIG. 2 shows a cross-section view 200 of NFC device 102. Test NFC device 102 includes a molding 202, a bezel 204, and a flexible printed circuit 206 sandwiched between the molding 202 and the bezel 204. Flexible printed circuit 206 includes various electronic components that may support one or more functions of NFC device 102 including, without limitation, an antenna, a processing device, a storage device, and so forth.

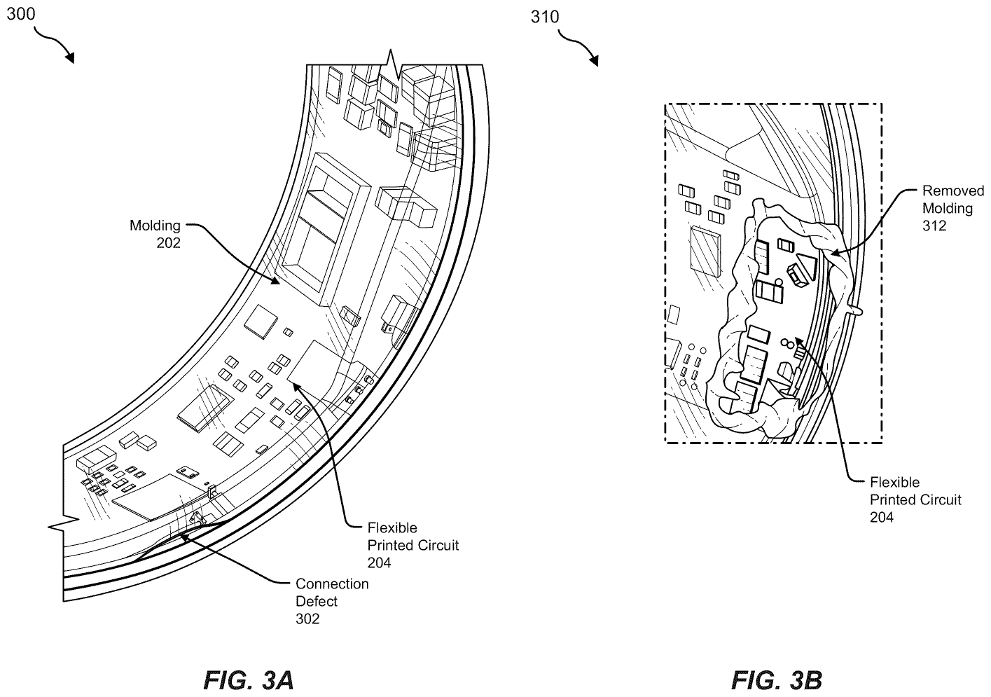

FIG. 3A shows a detailed view 300 of an interior surface of NFC device 102. In this example, molding 202 is partially transparent, allowing a view of flexible printed circuit 206 through molding 202. In the example illustrated in FIG. 3A, there is a connection defect 302 present in flexible printed circuit 206. Using conventional or traditional OTA testing apparatuses, systems, and methods, such a defect may only be discovered after application of molding 202. Hence, to repair the connection defect 302, molding 202 must be removed.

FIG. 3B shows a detailed view 310 of an interior surface of NFC device 102 following an attempt to repair connection defect 302. As shown by removed molding 312, molding 202 has been heavily damaged in order to provide repair access to flexible printed circuit 206. Such damage may not be easily and/or inexpensively repaired. Conversely, the indirect antenna testing apparatuses, systems, and methods disclosed herein may discover such defects prior to the application of a molding (e.g., molding 202) to a test NFC device, enabling a non-destructive repair of potential antenna or connection defects (e.g., connection defect 302).

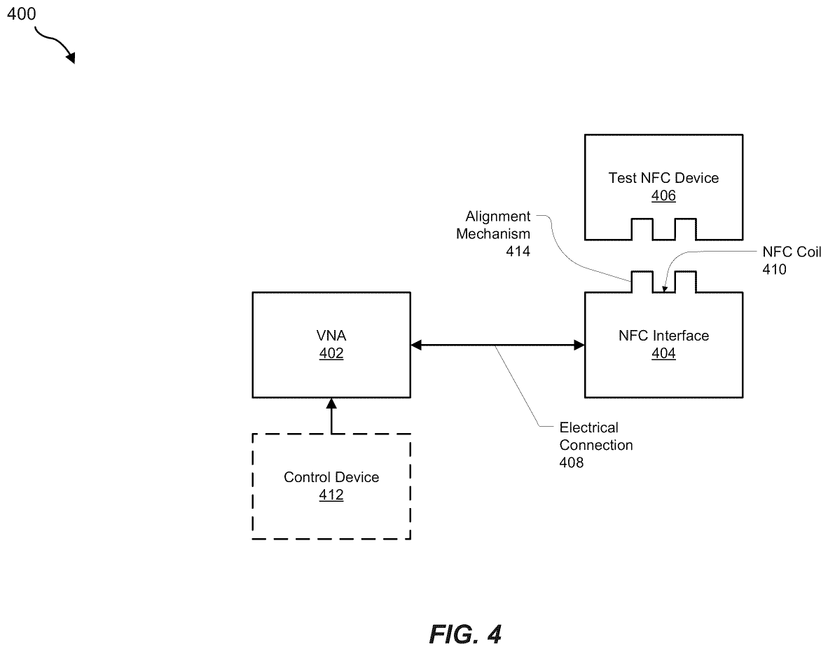

FIG. 4 shows a block diagram of an example indirect antenna testing apparatus 400. As shown, the indirect antenna testing apparatus includes a VNA 402 and an NFC interface 404. In some examples, a “vector network analyzer” or “VNA” may include an electronic device used to measure the network parameters of electrical networks. In some examples, a VNA can test both the amplitude and phase of the signal passing through a device under test and can operate over a wide range of frequencies. This may allow for a detailed characterization of a device's performance.

As shown in FIG. 4, VNA 402 is electrically coupled, via electrical connection 408, to NFC interface 404. NFC interface 404 may be configured to interact directly with NFC devices (e.g., test NFC device 406). NFC interface 404 includes an NFC coil 410 and is dimensioned or designed to receive and position a test NFC device 406 within an effective range of NFC coil 410. NFC coil 410 may be designed to generate an electromagnetic field when an electric current passes through it, enabling NFC. When a test NFC device is placed within the effective range of this coil, it allows for the transmission and reception of NFC signals between the device and the apparatus. In the testing process, the NFC coil is used by the Vector Network Analyzer (VNA) to emit a signal and then monitor for a resonance or response from the test NFC device, thereby assessing the functionality of the device's NFC capabilities.

NFC interface 404 may act as a conduit for electromagnetic signals, facilitating the transmission and reception of these signals to and from the NFC device, enabling VNA 402 to test NFC device 406 functionality by emitting a signal within a particular electromagnetic band and monitoring for a resonance. VNA 402 may be configured to emit signals through NFC coil 410 included in NFC interface 404 and monitor for resonance (e.g., caused by and/or from test NFC device 406) within certain electromagnetic bands.

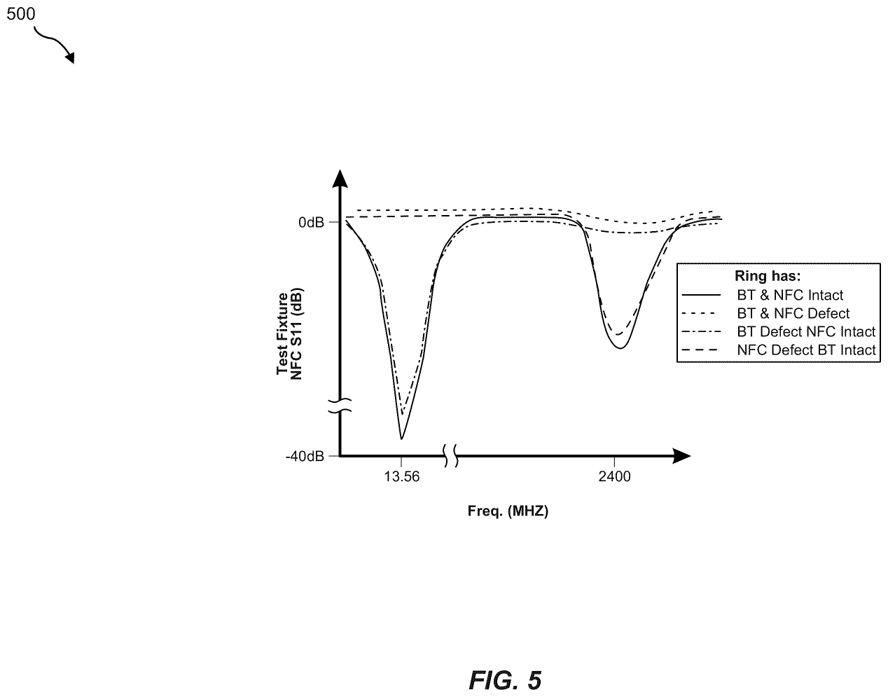

By way of illustration, FIG. 5 includes a plot 500 of resonances that VNA 402 may monitor for when testing a smart ring. Plot 500 includes four different lines corresponding to four different conditions that various resonances may indicate. As shown by a solid line, resonances may be detected within an electromagnetic band of approximately 13.56 megahertz and approximately 2,400 megahertz. A presence of these resonances may indicate that both an NFC antenna that operates within the approximate band of 13.56 megahertz and a Bluetooth antenna that operates within an electromagnetic band of approximately 2,400 megahertz are intact within NFC device 406 (i.e., there is no defect present).

Additionally, plot 500 also includes a half-dashed line that indicates no resonance at either of the 13.56-megahertz band or the 2,400-megahertz band. This may indicate that both an NFC antenna and a Bluetooth antenna may have defects. Next, plot 500 includes a line with a “dash-dot” pattern that indicates a resonance at the 13.56-megahertz band but not at the 2,400-megahertz band, which may indicate that there is no defect in an NFC antenna, but possibly a defect in a Bluetooth antenna. Plot 500 also includes a dashed line that indicates no resonance at 13.56 megahertz and a resonance at 2,400 megahertz. This may indicate that there is no defect in a Bluetooth antenna, but that there may be a defect in an NFC antenna.

Returning to FIG. 4, in some embodiments, indirect antenna testing apparatus 400 may also include (though optionally, as indicated by dashed lines) a control device 412. As will be described in greater detail below in reference to FIG. 14, control device 412 may include one or more devices or modules for performing one or more tasks, such as directing VNA 402 to emit a signal via NFC coil 410, monitor for a resonance from the NFC device 406, and so forth.

Furthermore, in some examples, indirect antenna testing apparatus 400 may also include an alignment mechanism 414. In some examples, alignment mechanism 414 may include any component or system within example indirect antenna testing apparatus 400 that ensures that test NFC device 406 is correctly positioned within an effective range of NFC coil 410. Alignment mechanism 414 may ensure optimal communication and interaction between NFC coil 410 and test NFC device 406, facilitating accurate testing and analysis of functionality of test NFC device 406 functionality.

Alignment mechanism 414 may include and/or incorporate any physical devices, systems, or techniques such as, without limitation, mechanical fixtures, guided slots, movable stages, automated systems, and so forth that may adjust a positioning of test NFC device 406 relative to NFC coil 410. One possible goal may be to ensure consistent and precise placement of the device being tested, leading to reliable and repeatable test results.

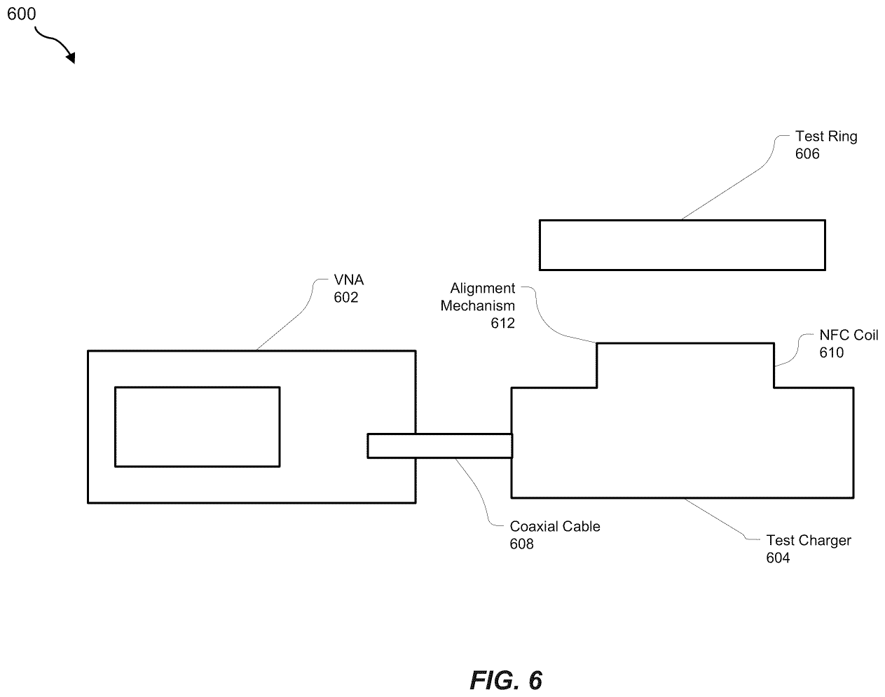

Example indirect antenna testing apparatus 400 in FIG. 4 may be implemented in a variety of ways. For example, all or a portion of example indirect antenna testing apparatus 400 may represent portions of an example indirect antenna testing apparatus 600 in FIG. 6.

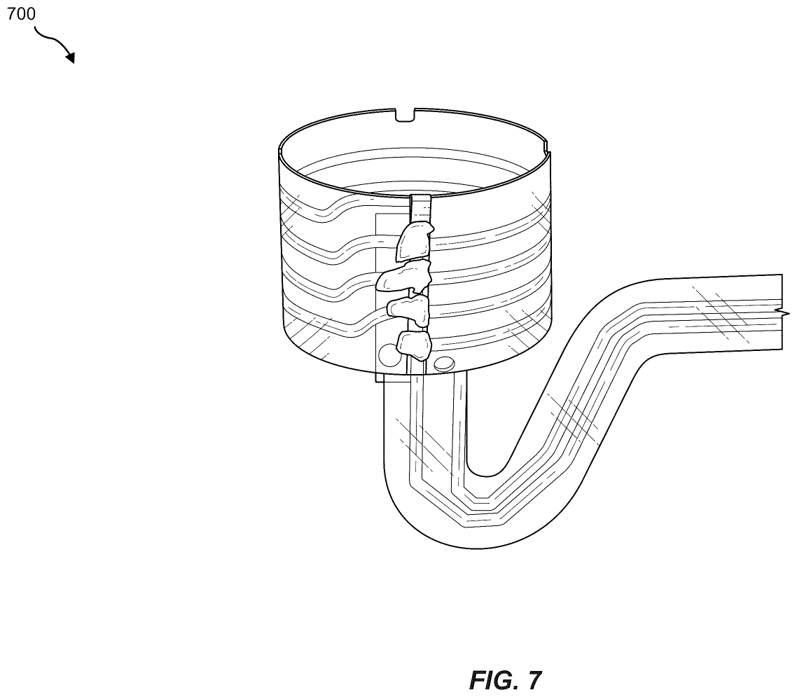

FIG. 6 is a block diagram of an example indirect antenna testing apparatus 600. As shown, indirect antenna testing apparatus 600 includes a VNA 602 that may implement VNA 402. Furthermore, in this example, NFC interface 404 may be implemented by test charger 604. Test charger 604 may be configured to provide electrical charge to one or more smart rings and may include a charging base with a built-in NFC coil 610, similar to NFC interface 404. NFC coil 610 may not only facilitate the transfer of electrical power from the charger to a smart ring but could also allow for communication between the two devices. FIG. 7 includes a perspective view 700 of an example NFC coil that may be included in and/or integrated into a test charger like test charger 604.

Returning to FIG. 6, test charger 604 may be dimensionally designed to receive and position a smart ring device in a favorable location for efficient power transfer, and hence may include a rest pillar or other mechanical alignment mechanism to ensure the smart ring is correctly positioned over the NFC coil.

When a smart ring is placed on the charging base, an electric current passed through NFC coil 610 could generate an electromagnetic field that the smart ring's NFC capabilities could convert back into electricity to charge its battery. Simultaneously, the charger and the smart ring could communicate via NFC.

As shown in FIG. 6, test charger 604 may be configured to receive a test ring 606. Test ring 606 may be a smart ring of any suitable configuration as described herein and may include any of a variety of antennas including, without limitation, an NFC antenna and/or a Bluetooth antenna.

In the configuration shown in FIG. 6, NFC coil 610 included in test charger 604 is electrically coupled to VNA 602 via a coaxial cable 608. In this configuration, VNA 602 may be configured to emit a signal via NFC coil 610 and monitor for a resonance from the test ring 606 within one or more electronic bands, as described above.

As mentioned above, test charger 604 is configured to receive test ring 606 and includes an alignment mechanism 612 in the form of a rest pillar that is dimensioned to receive test ring 606. A user or other suitable instrumentality (e.g., a mechanism) may place test ring 606 on the rest pillar (e.g., alignment mechanism 612) and the rest pillar may position and/or align test ring 606 within the effective range of NFC coil 610.

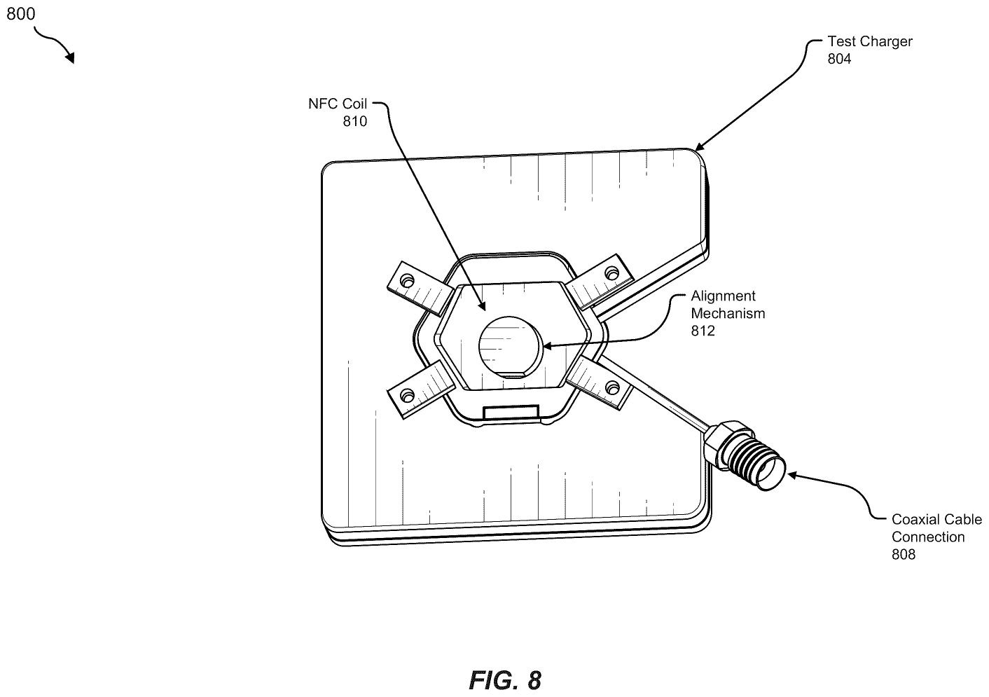

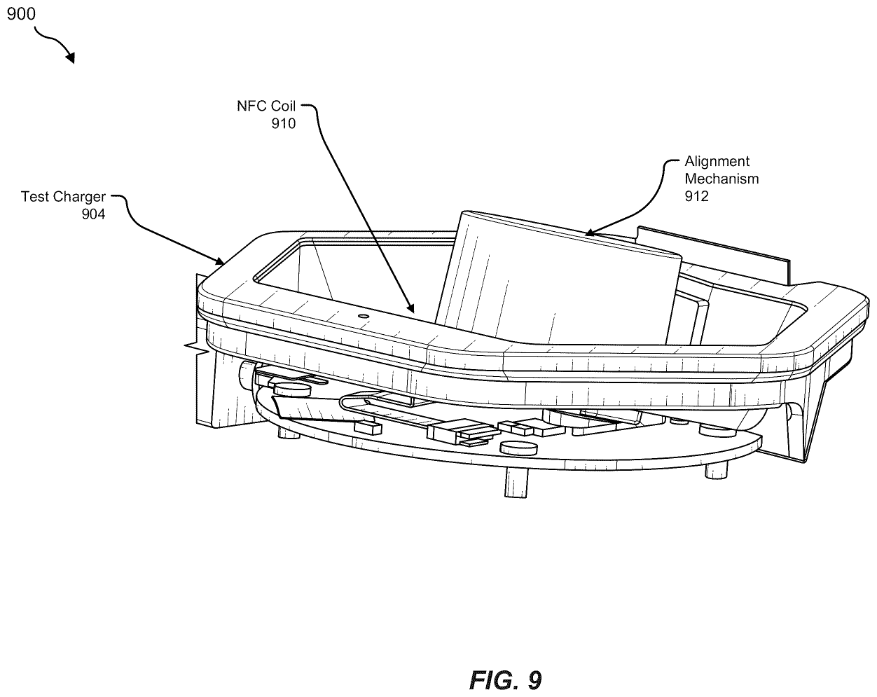

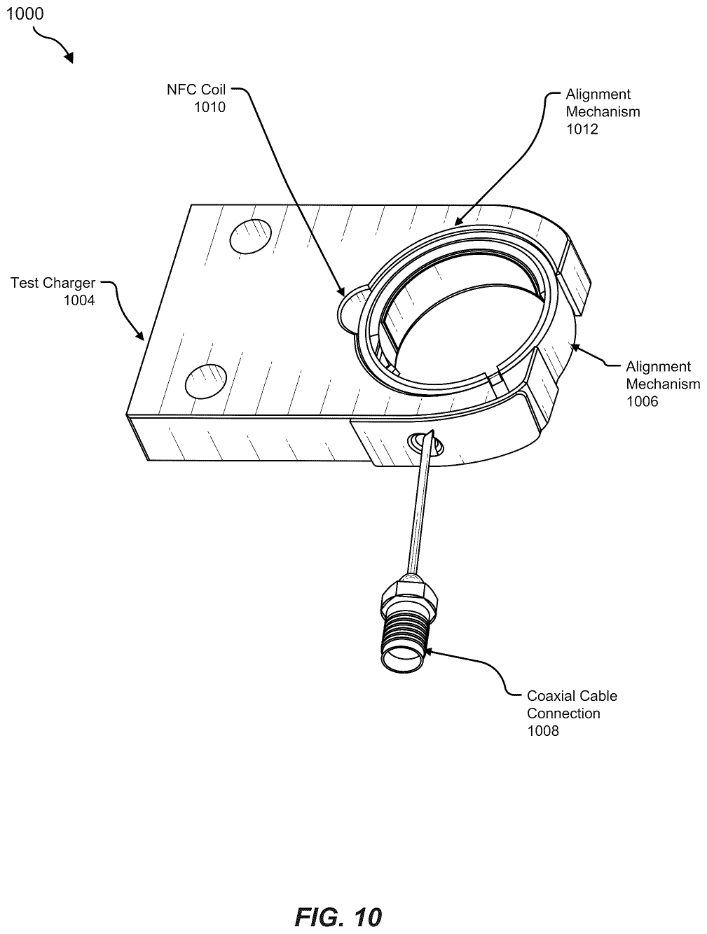

FIG. 8 shows a perspective view 800 of a test charger 804 that is like test charger 604. In this example, test charger 804 includes a coaxial cable connection 808 that may facilitate a coaxial cable link to a VNA device (e.g., VNA 402, VNA 602, etc.). Perspective view 800 also shows a position of an NFC coil 810 like NFC coil 610 and an alignment mechanism 812 in a form of a rest pillar dimensioned to receive a smart ring.

FIG. 9 shows a perspective view 900 of an additional test charger 904 that is also like test charger 604, but with a different configuration than test charger 804. In this example, alignment mechanism 912 and NFC Coil 910 are in a different orientation than, but perform similar functions to, alignment mechanism 812 and NFC coil 810. As shown, alignment mechanism 912, a rest pillar like alignment mechanism 812, is oriented at an angle off of a normal angle to a plane of a base surface of additional test charger 904. This may provide a different stability to and/or display angle for a smart ring received by additional test charger 904.

FIG. 10 shows a perspective view 1000 of an additional test charger 1004 that is also like test charger 604, but with a different physical configuration than test charger 804. In this example, test charger 1004 includes a coaxial cable connection 1008 that may facilitate a coaxial cable link to a VNA device (e.g., VNA 402, VNA 602, etc.). Perspective view 1000 also shows a position of an NFC coil 1010 like NFC coil 610 and an alignment mechanism 1012. In this example, alignment mechanism 1012 is configured to surround a test ring 1006 rather than support a test ring (e.g., via a rest pillar as in FIG. 6, FIG. 8, and FIG. 9. Furthermore, NFC coil 1010 is configured to surround test ring 1006. Although this configuration may vary from others described herein, this configuration may also enable any of the features disclosed herein.

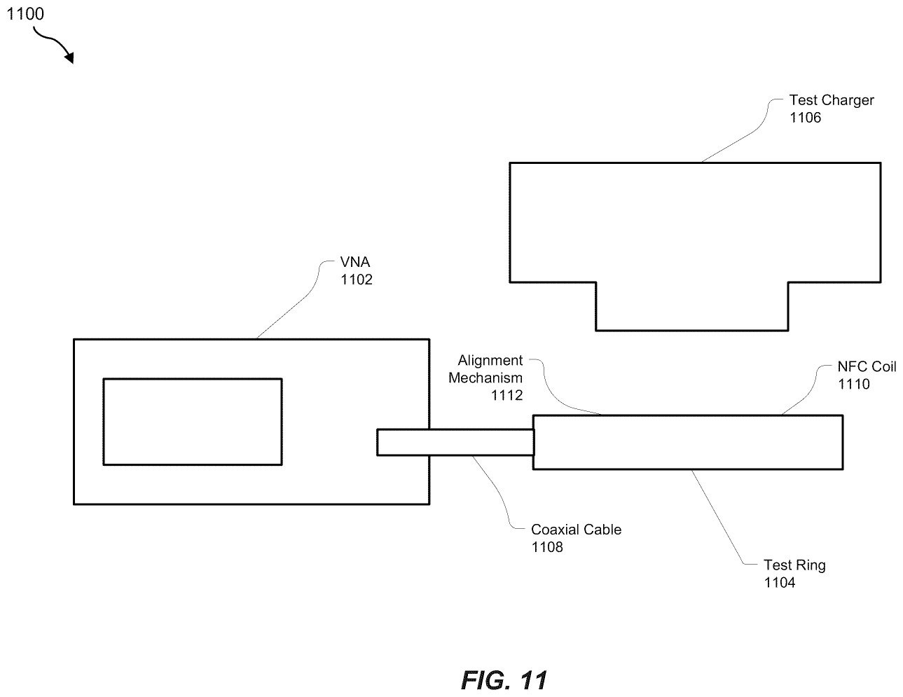

Given the nature of NFC devices, an NFC-equipped smart ring may, in some embodiments, function as an NFC interface to test functions of NFC antennas or coils within test chargers. FIG. 11 includes a block diagram 1100 that illustrates using a smart ring device, shown in FIG. 11 as test ring 1104, as an NFC interface like NFC interface 404. Like in FIG. 6, FIG. 11 also includes a VNA 1102 connected to test ring 1104 via a coaxial cable connection 1108. As illustrated, test ring 1104 includes an NFC antenna or coil, denoted in FIG. 11 as NFC coil 1110. In this example, the NFC device being tested is a test charger 1106. As with other NFC interfaces disclosed herein (e.g., NFC interface 404, test charger 604, test charger 804, additional test charger 1004, etc.), test ring 1104 is configured to receive test charger 1106. In this example, test ring 1104 may receive test charger 1106 via insertion of a rest pillar included in test charger 1106 into test ring 1104. In such an example, a portion of test ring 1104 may also function as an alignment mechanism 1112 that automatically aligns the test charger 1106 within an effective range of NFC coil 1110.

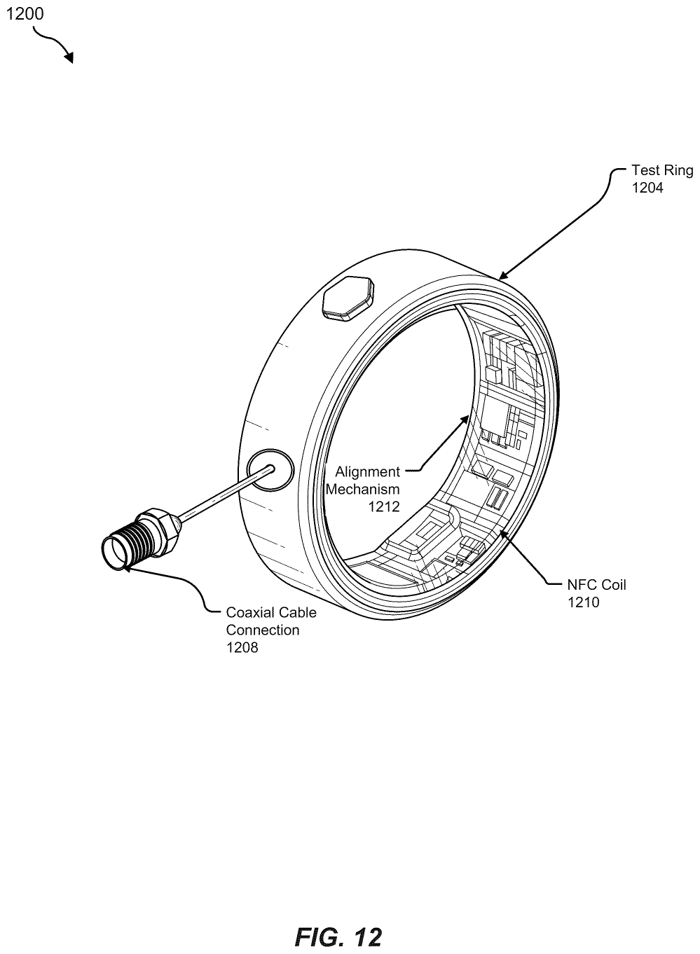

FIG. 12 shows a perspective view 1200 of a test ring 1204 that is like test ring 1104. In this example, test ring 1204 includes a coaxial cable connection 1208 that may facilitate a coaxial cable link to a VNA device (e.g., VNA 402, VNA 602, etc.). Perspective view 1200 also shows a position of an NFC coil 1210 like NFC coil 610 and an alignment mechanism 1212 in a form of a body of test ring 1204 that is dimensioned to receive a rest pillar of a test charger (e.g., test charger 1106).

In the configurations shown in FIG. 11 and FIG. 12, embodiments of the systems and methods described herein may identify NFC antenna defects within charger boxes much as other embodiments may identify antenna defects in other devices. A VNA device (e.g., VNA 1102) may emit a signal via NFC coil 1110 and may monitor for a resonance from test charger 1106 within a predetermined electromagnetic band. An absence of resonance in a particular target electromagnetic band may indicate that an NFC antenna within test charger 1106 has a defect.

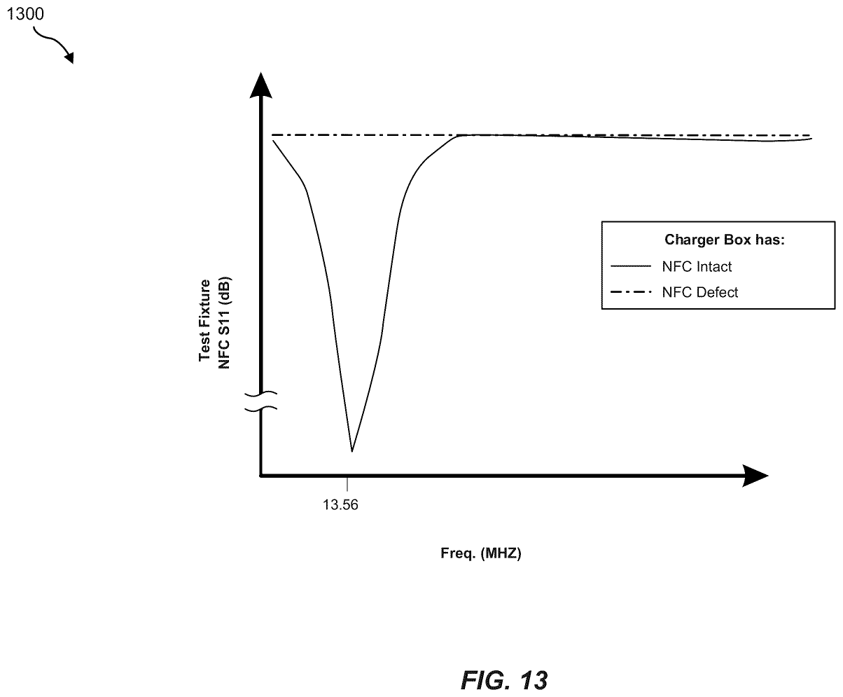

By way of illustration, FIG. 13 includes a plot 1300 of resonances that VNA 1102 may monitor for when testing a charger box (e.g., test charger 1106). Plot 1300 includes two different lines corresponding to two different conditions. As shown by a solid line, a resonance may be detected within an electromagnetic band of approximately 13.56 megahertz. This resonance may indicate that an NFC antenna is intact within test charger 1106 (i.e., there is no defect present). Conversely, plot 1300 also includes a line with a “dash-dot” pattern that indicates no resonance. This may indicate that an NFC antenna included in test charger 1106 has a defect.

FIG. 14 is a block diagram of an example control device 1400 for indirect antenna testing. The components and functions illustrated by example control device 1400 may be included in and/or performed by any of the control devices described herein, such as control device 412. Items illustrated by dashed lines may be omitted from some embodiments.

As illustrated in this figure, example control device 1400 may include one or more modules 1402 for performing one or more tasks. As will be explained in greater detail below, modules 1402 may include a directing module 1404 that may direct a VNA electrically coupled to an NFC coil to (1) emit a signal via the NFC coil, and (2) monitor for a resonance from the test NFC device within at least one predetermined electromagnetic band. Additionally, in some embodiments, example control device 1400 may also include a determining module 1406 that may determine whether the VNA detects the resonance. Upon determining that the VNA detects the resonance, determining module 1406 may designate the test NFC device with a status of functional. Conversely, upon determining that the VNA does not detect the resonance, determining module 1406 may designate the test NFC device with a status of faulty. Continuing with the previous example, determining module 1406 may determine whether VNA 402 detects a resonance within the 13.56-megahertz band. Upon determining that the VNA 402 detects the resonance, determining module 1406 may designate NFC device 406 with a status of functional. Conversely, upon determining that VNA 402 does not detect the resonance, determining module 1406 may designate NFC device 406 with a status of faulty. Determining module 1406 may perform these operations in any of the ways described herein.

As also shown in FIG. 14, example control device 1400 may include a reporting module 1408 that may (1) log a determined status of an NFC device, and/or (2) report the determined status of the NFC device to a user. For example, reporting module 1408 may log a determined status of NFC device 406 within or as part of reporting data 1444 described below. Additionally or alternatively, reporting module 1408 may report the determined status of NFC device 406 to a user via data included in reporting data 1444

As further illustrated in FIG. 14, example control device 1400 may also include one or more memory devices, such as memory 1420. Memory 1420 generally represents any type or form of volatile or non-volatile storage device or medium capable of storing data and/or computer-readable instructions. In one example, memory 1420 may store, load, and/or maintain one or more of modules 1402. Examples of memory 1420 include, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage memory.

As further illustrated in FIG. 14, example control device 1400 may also include one or more physical processors, such as physical processor 1430. Physical processor 1430 generally represents any type or form of hardware-implemented processing unit capable of interpreting and/or executing computer-readable instructions. In one example, physical processor 1430 may access and/or modify one or more of modules 1402 stored in memory 1420. Additionally or alternatively, physical processor 1430 may execute one or more of modules 1402 to facilitate indirect antenna testing. Examples of physical processor 1430 include, without limitation, microprocessors, microcontrollers, central processing units (CPUs), Field-Programmable Gate Arrays (FPGAs) that implement softcore processors, Application-Specific Integrated Circuits (ASICs), portions of one or more of the same, variations or combinations of one or more of the same, or any other suitable physical processor.

As also illustrated in FIG. 14, example control device 1400 may also include one or more stores of data, such as data store 1440. Data store 1440 may represent portions of a single data store or computing device or a plurality of data stores or computing devices. In some embodiments, data store 1440 may be a logical container for data and may be implemented in various forms (e.g., a database, a file, file system, a data structure, etc.). Examples of data store 1440 may include, without limitation, one or more files, file systems, data stores, databases, and/or database management systems such as an operational data store (ODS), a relational database, a NoSQL database, a NewSQL database, and/or any other suitable organized collection of data.

In at least one example, data store 1440 may include resonance data 1442 that may include information associated with directing a VNA (e.g., VNA 1450, described below) to (1) emit a signal via an NFC coil, and (2) monitor for a resonance from a test NFC device within at least one predetermined electromagnetic band. For example, resonance data 1442 may include data associated with frequencies or bands associated with antennas to be tested, resonances to be detected, and so forth.

Additionally, as shown in FIG. 14, data store 1440 may also include reporting data 1444 that may include data for reporting defective and/or intact NFC devices such as user data, telecommunications data, networking data, pre-generated reports, and so forth.

As is further shown in FIG. 14, example control device 1400 may also include a VNA 1450. VNA 1450 may include any suitable VNA including any of the VNA devices described herein (e.g., VNA 402, VNA 602, VNA 1102, etc.). Although shown as part of control device 1400, VNA 1450 may be physically separate from other components included in control device 1400. Additionally or alternatively, control device 1400 may be included in and/or incorporated as part of any of the VNAs described herein. Although not shown in FIG. 14, VNA 1450 may be electrically coupled to one or more NFC interfaces, such as NFC interface 404, test charger 604, test charger 804, additional test charger 904, additional test charger 1004, test ring 1104, and so forth.

FIG. 15 is a flow diagram of an example method 1500 for indirect antenna testing. The steps shown in FIG. 15 may be performed by any suitable computer-executable code and/or computing system, including example control device 1400 in FIG. 14, example control device 412 in FIG. 4, and/or variations or combinations of one or more of the same. In one example, each of the steps shown in FIG. 15 may represent an algorithm whose structure includes and/or is represented by multiple sub-steps, examples of which will be provided in greater detail below.

As illustrated in FIG. 15, at step 1510, one or more of the systems or control devices described herein may direct a VNA electrically coupled to an NFC coil to (1) emit a signal via the NFC coil. For example, as described above, directing module 1404 may direct VNA 402 electrically coupled to NFC coil 410 to emit a signal within a 13.56-megahertz band, and may monitor for a resonance from NFC device 406 within the 13.56-megahertz band.

At step 1520, one or more of the systems or control devices described herein may direct a VNA electrically coupled to an NFC coil to monitor for a resonance from a test NFC device within at least one predetermined electromagnetic band. For example, as described above, directing module 1404 may direct VNA 402 electrically coupled to NFC coil 410 to monitor for a resonance from determining module 1406 within a predetermined electromagnetic band. Continuing with the example above, directing module 1404 may direct VNA 402 electrically coupled to NFC coil 410 to monitor for a resonance from NFC device 406 within the 13.56-megahertz band. Directing module 1404 may perform these directing operations in any of the ways described herein.

Continuing to step 1530, one or more of the systems or control devices described herein may determine whether the VNA detects the resonance. For example, determining module 1406 may determine whether VNA 402 detects the resonance.

In step 1540, upon determining that the VNA detects the resonance, one or more of the systems or control devices described herein may designate the test NFC device with a status of functional. For example, determining module 1406 may designate the test NFC device with a status of functional. Conversely, at step 1550, upon determining that the VNA does not detect the resonance, one or more of the systems or control units described herein may designate the test NFC device with a status of faulty. For example, determining module 1406 may, upon determining that VNA 402 does not detect the resonance, determining module 1406 may designate determining module 1406 with a status of faulty.

Continuing with the previous example, determining module 1406 may determine whether VNA 402 detects a resonance within the 13.56-megahertz band. Upon determining that the VNA 402 detects the resonance, determining module 1406 may designate NFC device 406 with a status of functional. Conversely, upon determining that VNA 402 does not detect the resonance, determining module 1406 may designate NFC device 406 with a status of faulty. Determining module 1406 may perform these operations in any of the ways described herein.

In additional or alternative examples, one or more of the systems or control devices described herein may (1) log a determined status of a test NFC device, and/or (2) report a determined status of the test NFC device to a user. For example, as described above, reporting module 1408 may log a determined status of NFC device 406 within or as part of reporting data 1444, and/or reporting module 1408 may report the determined status of NFC device 406 to a user via user telecommunication data included in reporting data 1444.

In light of the challenges faced by typical smart wearables during production, particularly those related to testing and repairs, the apparatuses, systems, and methods disclosed herein may provide many benefits, including intercepting defects in devices before the devices are fully assembled. In contrast to conventional OTA testing that is often time-consuming and costly, embodiments of this disclosure may offer faster results and may reduce costs since it may be conducted pre-molding. The indirect testing is facilitated by a VNA connected to a test fixture equipped with an NFC coil or antenna. The system can quickly identify defects by observing the absence of resonance at the respective technology bands (13.56 megahertz for NFC and 2,400 megahertz for Bluetooth). The devices identified with defects may then be removed from an assembly line and repaired, which is made easier as they have not yet undergone the molding process.

In at least one embodiment, the VNA may be connected to the test fixture via a VNA port and a coax cable. The NFC test fixture may include a rest pillar dimensioned to accommodate a test ring. In another embodiment, the test ring itself may be repurposed as a test fixture for charging boxes, allowing for quick testing of charger boxes. Here, the VNA may be connected to the test ring via a VNA port and a coax cable. This embodiment features a test fixture designed to resemble a test ring, with dimensions that can receive a rest pillar of a test fixture. This approach enhances the efficiency and cost-effectiveness of the testing process, making it a viable solution for the manufacture of smart wearables.

As detailed above, the computing devices and systems described and/or illustrated herein broadly represent any type or form of computing device or system capable of executing computer-readable instructions, such as those contained within the modules described herein. In their most basic configuration, these computing device(s) may each include at least one memory device and at least one physical processor.

Although illustrated as separate elements, the modules described and/or illustrated herein may represent portions of a single module or application. In addition, in certain embodiments one or more of these modules may represent one or more software applications or programs that, when executed by a computing device, may cause the computing device to perform one or more tasks. For example, one or more of the modules described and/or illustrated herein may represent modules stored and configured to run on one or more of the computing devices or systems described and/or illustrated herein. One or more of these modules may also represent all or portions of one or more special-purpose computers configured to perform one or more tasks.

In addition, one or more of the modules described herein may transform data, physical devices, and/or representations of physical devices from one form to another. For example, one or more of the modules recited herein may receive frequency or resonance data to be transformed, transform the frequency or resonance data, output a result of the transformation to determine whether a defect exists in an antenna included in an NFC device, use the result of the transformation to direct a control device to perform an action, and store the result of the transformation to test additional devices. Additionally or alternatively, one or more of the modules recited herein may transform a processor, volatile memory, non-volatile memory, and/or any other portion of a physical computing device from one form to another by executing on the computing device, storing data on the computing device, and/or otherwise interacting with the computing device.

The term “computer-readable medium,” as used herein, generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the instant disclosure. The embodiments disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An apparatus comprising:
a Near Field Communication (NFC) interface comprising an NFC coil, the NFC interface dimensioned to receive a test NFC device while positioning the test NFC device within an effective range of the NFC coil;
a Vector Network Analyzer (VNA) electrically coupled to the NFC coil and configured to:
emit a signal via the NFC coil; and
monitor for a resonance from the test NFC device within at least one predetermined electromagnetic band.

2. The apparatus of claim 1, wherein:
the test NFC device comprises a smart ring device; and
the NFC interface comprises a pillar dimensioned to receive the smart ring device.

3. The apparatus of claim 1, wherein:
the test NFC device comprises a pillar dimensioned to receive a smart ring device; and
the NFC interface comprises a smart ring device.

4. The apparatus of claim 1, wherein the at least one predetermined electromagnetic band comprises at least one of:
an electromagnetic band corresponding to NFC signals; and
an electromagnetic band corresponding to Bluetooth signals.

5. The apparatus of claim 1, wherein the at least one predetermined electromagnetic band comprises at least one of:
13.56 megahertz; and
2,400 megahertz.

6. The apparatus of claim 1, further comprising an alignment mechanism that automatically aligns the test NFC device within the effective range of the NFC coil.

7. The apparatus of claim 1, wherein the test NFC device comprises at least one of:
a smart ring device;
a smart glasses device;
a smart watch device;
an NFC tracker device; and
an NFC key fob device.

8. The apparatus of claim 1, wherein the test NFC device comprises a partially assembled NFC device.

9. The apparatus of claim 1, further comprising a control device that directs the VNA to:
emit the signal via the NFC coil; and
monitor for the resonance from the test NFC device within the at least one predetermined electromagnetic band.

10. The apparatus of claim 9, wherein the control device further:
determines whether the VNA detects the resonance;
upon determining that the VNA detects the resonance, designates the test NFC device with a status of functional; and
upon determining that the VNA does not detect the resonance, designates the test NFC device with a status of faulty.

11. The apparatus of claim 10, wherein the control device further logs a determined status of the test NFC device.

12. The apparatus of claim 10, wherein the control device further reports a determined status of the test NFC device to a user.

13. A system comprising:
an indirect antenna testing apparatus comprising:
a Near Field Communication (NFC) interface comprising an NFC coil, the NFC interface dimensioned to receive a test NFC device while positioning the test NFC device within an effective range of the NFC coil;
a Vector Network Analyzer (VNA) electrically coupled to the NFC coil and configured to:
emit a signal via the NFC coil;
monitor for a resonance from the test NFC device within at least one predetermined electromagnetic band;
a control device comprising:
a directing module, stored in memory, that directs the VNA to:
emit the signal via the NFC coil;
monitor for the resonance from the test NFC device; and
at least one physical processor that executes the directing module.

14. The system of claim 13, wherein:
the control device further comprises a determining module, stored in memory, that:
determines whether the VNA detects the resonance;
upon determining that the VNA detects the resonance, designates the test NFC device with a status of functional;
upon determining that the VNA does not detect the resonance, designates the test NFC device with a status of faulty; and
the at least one physical processor further executes the determining module.

15. The system of claim 14, wherein:
the control device further comprises a reporting module, stored in memory, that at least one of:
logs a determined status of the test NFC device;
reports the determined status of the test NFC device to a user; and
the at least one physical processor further executes the reporting module.

16. The system of claim 13, wherein the indirect antenna testing apparatus further comprises an alignment mechanism that automatically aligns the test NFC device within the effective range of the NFC coil.

17. A method comprising:
directing a Vector Network Analyzer (VNA) electrically coupled to an NFC coil included in an NFC interface to:
emit a signal via the NFC coil;
monitor for a resonance from a test NFC device within at least one predetermined electromagnetic band;
wherein:
the NFC interface is dimensioned to receive the test NFC device while positioning the test NFC device within an effective range of an NFC coil included in the NFC interface; and
the NFC device is received by the NFC interface.

18. The method of claim 17, further comprising:
determining whether the VNA detects the resonance;
upon determining that the VNA detects the resonance, designating the test NFC device with a status of functional; and
upon determining that the VNA does not detect the resonance, designating the test NFC device with a status of faulty.

19. The method of claim 18, further comprising at least one of:
logging a determined status of the test NFC device; and
reporting the determined status of the test NFC device to a user.

20. The method of claim 17, further comprising automatically aligning, prior to directing the VNA to emit the signal via the NFC coil, via an alignment mechanism included in the NFC interface, the test NFC device within the effective range of the NFC coil.
